(19) United States
(12) Patent Application Publication
(10) Pub. No.: US 2017/0025816 A1
(43) Pub. Date: Jan. 26, 2017

(54) LASER DRIVER WITH VARIABLE RESISTOR AND VARIABLE CAPACITANCE ELEMENT, AND OPTICAL TRANSMITTER INCLUDING THE SAME

(71) Applicant: SUMITOMO ELECTRIC INDUSTRIES, LTD., Osaka (JP)

(72) Inventor: Keiji TANAKA, Yokohama-shi (JP)

(21) Appl. No.: 15/208,310

(22) Filed: Jul. 12, 2016

(30) Foreign Application Priority Data
Jul. 21, 2015 (JP) 2015-143666

(51) Int. Cl. H01S 5/042; H04B 10/50

(52) U.S. Cl. CPC H01S 5/042; H04B 10/503

(57) ABSTRACT

A laser driver includes a differential amplifier and a driver. The differential amplifier includes a first series circuit and a second series circuit each including a resistor, a transistor, and a current source that are connected in series to each other, a variable resistor connected between emitters of the transistors, and a variable capacitance element connected in parallel to the variable resistor. The differential amplifier generates a driving signal having amplitude proportional to amplitude of a differential signal externally input to the transistors. The driver generates a driving current in response to the driving signal for driving the semiconductor laser connected in series to the driver. The laser driver changes frequency characteristics of the differential amplifier by adjusting the variable resistor and the variable capacitance element to correct frequency characteristics of the semiconductor laser. The laser driver may improve eye opening of an optical signal output from the semiconductor laser.

### BACKGROUND OF THE INVENTION

1. Field of the Invention

The present invention relates to a laser driver for driving a semiconductor laser element and further relates to an optical transmitter that includes the laser driver. The optical transmitter is mainly used in fiber optic communication.

2. Description of the Related Art

US Patent Application Publication No. 2010/0092184 describes an optical transmission module in which a laser driver is adapted. The laser driver described in the patent document receives a differential signal and outputs a driving signal for driving a semiconductor laser. The laser driver includes a pair of transistors, a current source, a resistive element, an emitter follower, and an amplifying transistor. At the pair of transistors, a current supplied from the current source is distributed to the transistors in response to the differential signal. The current that is distributed to one of the pair of transistors is converted into the driving signal by the resistive element. The amplifying transistor is connected in series to the cathode of a semiconductor laser element. The driving signal is input to the control terminal of the amplifying transistor through the emitter follower. An optical signal that is output from the semiconductor laser is modulated in response to the driving signal.

### SUMMARY OF THE INVENTION

A laser driver according to an aspect of the present invention generates a driving current for driving a semiconductor laser element in response to a differential signal input from outside the laser driver. The laser driver includes a differential amplifier and a driver. The differential amplifier includes a first series circuit, a second series circuit, a variable resistor, and a variable capacitance element. The first series circuit includes a first transistor, a first resistor, and a first current source. The first transistor includes a first current terminal, a second current terminal, and a control terminal. The first resistor includes a first terminal and a second terminal. The first current source includes a first terminal and a second terminal. The first terminal of the first resistor is connected to the first current terminal of the first transistor. The first terminal of the first current source is connected to the second current terminal of the first transistor. The second series circuit includes a second transistor, a second resistor, and a second current source. The second transistor includes a first current terminal, a second current terminal, and a control terminal. The second resistor includes a first terminal and a second terminal. The second current source includes a first terminal and a second terminal. The first terminal of the second resistor is connected to the first current terminal of the second transistor. The first terminal of the second current source is connected to the second current terminal of the second transistor. The second terminal of the second resistor is connected to the second terminal of the first resistor. The second terminal of the second current source is connected to the second terminal of the first current source. The variable resistor includes a first terminal and a second terminal, and has a variable resistance between the first terminal and the second terminal thereof. The first terminal of the variable resistor being connected to the second current terminal of the first transistor, and the second terminal of the variable resistor is connected to the second current terminal of the second transistor. The variable capacitance element includes a first terminal and a second terminal, and has a variable capacitance between the first terminal and the second terminal thereof. The first terminal of the variable capacitance element is connected to the first terminal of the variable resistor, and the second terminal of the variable capacitance element is connected to the second terminal of the variable resistor. The control terminal of the first transistor and the control terminal of the second transistor are configured to complimentarily receive the differential signal. One of the first current terminal of the first transistor and the first current terminal of the second transistor is configured to output a driving signal in response to the differential signal. The driver is configured to generate the driving current in response to the driving signal, and supply the driving current to the semiconductor laser element.

The laser driver may correct the frequency characteristics of the semiconductor laser element by adjusting the variable resistor and the variable capacitance element and consequently changing frequency characteristics of the differential amplifier for improving eye opening of the optical signal.

### BRIEF DESCRIPTION OF THE DRAWINGS

FIG. 1 is a block diagram illustrating an internal configuration of an optical transmitter according to an embodiment of the present invention.

FIG. 2 is a schematic diagram of a laser driver shown in FIG. 1.

FIG. 3 is a diagram illustrating the relationship between the laser current of a laser diode and the optical output power, and an example of the waveform of optical output in a case where the differential signal is a Pulse Amplitude Modulation-4 (PAM-4) signal.

FIG. 4 includes graphs representing the relationships between the differential signal voltage and the collector currents of transistors.

FIG. 5 is a graph representing the frequency characteristics of the voltage gain of a differential amplifier.

FIGS. 6A to 6C are graphs representing the frequency-gain characteristics for visually explaining advantages attained by an embodiment of the present invention.

FIGS. 7A to 7C are graphs representing the frequency-gain characteristics in a first comparative example.

FIGS. 8A to 8C are graphs representing the frequency-gain characteristics in a second comparative example.

FIGS. 9A to 9E represent signal waveforms (eye-patterns) produced by the laser driver of an embodiment of the present invention.

FIGS. 10A to 10E repersent signal waveforms (eye-patterns) produced in the first comparative example.

FIGS. 11A to 11E represent signal waveforms (eye-patterns) produced in the second comparative example.

### DESCRIPTION OF THE PREFERRED EMBODIMENTS

Specific examples of a laser driver according to an embodiment of the present invention are explained below with reference to the drawings. Note that the present invention is not restricted to the examples and is intended to include all changes shown according to the appended claims and falling within the meaning and scope of equivalence of the appended claims. In the following explanations, the same elements are given the same signs in the explanations of the drawings, and a duplicated explanation is omitted.

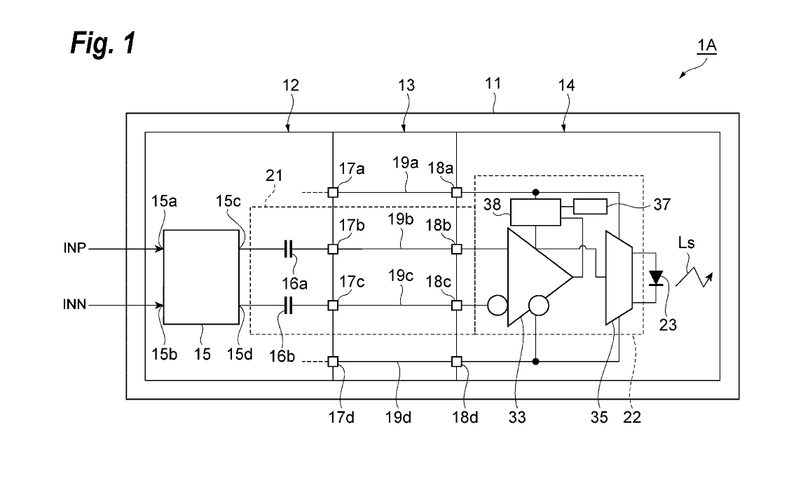

FIG. 1 is a block diagram illustrating an internal configuration of an optical transmitter 1A according to an embodiment of the present invention. As shown in FIG. 1, the optical transmitter 1A of this embodiment includes a housing 11, a print circuit board (PCB) 12, a flexible print circuit (FPC) 13, and a transmitter optical sub-assembly (TOSA) 14. The housing 11 houses the PCB 12, the FPC 13, and the TOSA 14. The FPC 13 includes terminals 17a to 17d on one end and terminals 18a to 18d on the other end. In the housing 11, the PCB 12 is electrically coupled to the terminals 17a to 17d of the FPC 13. In the FPC 13, the terminals 17a to 17d are electrically coupled to the terminals 18a to 18d through wiring lines (interconnections) 19a to 19d respectively. In the housing 11, the terminals 18a to 18d of the FPC 13 are electrically coupled to the TOSA 14. More specifically, the terminals 18a to 18d of the FPC 13 are electrically coupled to a laser driver 22 (under-mentioned) within the TOSA 14.

The PCB 12 includes a clock data recovery (CDR) circuit 15 and coupling capacitors 16a and 16b. The CDR circuit 15 includes a pair of input terminals 15a and 15b and a pair of output terminals 15c and 15d. The input terminals 15a and 15b receive a differential input signal input from outside the optical transmitter 1A. The differential input signal consists of a positive-phase input signal INP and a negative-phase input signal INN. The positive-phase input signal INP and the negative-phase input signal INN are a pair of complementary signals and have phases different from each other by 180°. The positive-phase input signal INP is input to the input terminal 15a, and the negative-phase input signal INN is input to the input terminal 15b. The CDR circuit 15 reshapes waveforms of the differential input signal and outputs the differential input signal obtained after reshaping as a differential output signal. The positive-phase input signal INP and the negative-phase input signal INN obtained after reshaping are output from the output terminals 15c and 15d respectively. The differential output signal consists of a positive-phase output signal and a negative-phase output signal. The positive-phase output signal and the negative-phase output signal are a pair of complementary signals and have phases different from each other by 180°. The output terminals 15c and 15d of the CDR circuit 15 are electrically coupled to the terminals 17b and 17c of the FPC 13 through the coupling capacitors 16a and 16b respectively. That is, the positive-phase input signal INP obtained after reshaping (positive-phase output signal) and the negative-phase input signal INN obtained after reshaping (negative-phase output signal) are input to the laser driver 22 of the TOSA 14 through the terminals 17b and 17c, the wiring lines (interconnections) 19b and 19c, and the terminals 18b and 18c respectively. In short, the differential output signal of the CDR circuit 15 is input to the laser driver 22. Note that wiring elements that electrically couple the CDR circuit 15 with the laser driver 22 constitute a transmission line 21 suitable to transmit high frequency signals.

The terminal 17a is connected to the power line (not shown) of the PCB 12. The PCB 12 supplies a supply voltage to the laser driver 22 of the TOSA 14 through the terminal 17a, the wiring line (interconnection) 19a, and the terminal 18a. The terminal 17d is connected to the reference potential line (GND line, not shown) of the PCB 12. The PCB 12 supplies a reference potential to the laser driver 22 of the TOSA 14 through the terminal 17d, the wiring line (interconnection) 19d, and the terminal 18d.

The TOSA 14 includes the laser driver 22 and a laser diode 23 (semiconductor laser element). The laser driver 22 drives the laser diode 23 in response to the differential output signal output from the CDR circuit 15. In more detail, the laser driver 22 includes a differential amplifier 33, a driver 35, an adjusting circuit 38, and a target potential circuit 37. The differential amplifier 33 is constituted by a continuous-time linear equalizer (CTLE), for example. The differential amplifier 33 receives the positive-phase input signal INP and the negative-phase input signal INN through the terminals 18b and 18c and generates a driving signal on the basis of the negative-phase input signal INN. The driver 35 receives the driving signal generated by the differential amplifier 33 and generates an output current for driving the laser diode 23 in response to the driving signal. The driver 35 includes an output terminal and outputs the output current from the output terminal. The output terminal of the driver 35 is connected in series to the laser diode 23. Accordingly, the output current of the driver 35 flows through the laser diode 23. In this way, the output current of the driver 35 is generated in response to the differential input signal, and an optical signal to be output from the laser diode 23 is modulated accordingly. The target potential circuit 37 generates a target potential and supplies the target potential to the adjusting circuit 38. The adjusting circuit 38 monitors the average potential (common potential) of the driving signal output from the differential amplifier 33 and adjusts the average potential of the driving signal of the differential amplifier 33 so that the average potential becomes substantially equal to the target potential. As a result, the average potential (common potential) of the driving signal is maintained substantially equal to the target potential. As described above, the supply voltage and the reference potential (GND) of the laser driver 22 are provided from the PCB 12 through the terminals 18a and 18d respectively.

The laser diode 23 has an anode and a cathode. The anode of the laser diode 23 is electrically coupled to the power line of the laser driver 22. The cathode of the laser diode 23 is electrically coupled to the output terminal of the driver 35. The laser diode 23 generates an optical signal Ls in response to the output current output from the output terminal of the driver 35. The optical signal Ls is output (transmitted) outside the optical transmitter 1A through an optical waveguide (not shown, an optical fiber, for example) connected to the TOSA 14.

Now, an issue of optical transmitters is explained. With the increase in the transmission speed of optical transmission systems, the modulation rate of semiconductor laser elements has increased to a speed of 28 Gb/s, for example. Accordingly, Speed of a differential input signal provided to a laser driver for driving a semiconductor laser element has been increased. However, on a transmission line for transmitting the differential input signal to the laser driver, high frequency signals are deteriorted in the PCB or in the FPC due to a conductor loss, a dielectric loss, and so on. Therefore, it is often the case that the waveform osf the differential input signal are deteriorated not only outside the optical transmitter but also inside the optical transmitter before the differential input signal reaches the laser driver. The CDR circuit receives the differential input signal having such deteriorated waveforms and reproduces the waveforms of the differential input signal before deterioration. However, regarding a high-speed differential signal of 28 Gb/s or more, which is faster than the previous generation speed of 10 Gb/s, for example, the signal waveform reproduced by the CDR circuit is deteriorated again before the signal reaches the laser driver, and therefore, an optical signal modulated in accordance with the signal waveforms is also deteriorated.

In a case where the differential input signal is a binary signal that only includes two values of a low level and a high level, the low level and the high level of the signal waveforms are limited to constant values respectively by setting the amplitude of the differential input signal to a value larger than the range of linear amplification of the laser driver, for example. As a result, the signal waveforms can be improved. However, it is not possible to apply this technique in a case where the laser driver needs to operate within the range of linear amplification, such as in a case where the differential input signal is a multi-value pulse amplitude modulated signal (PAM signal), for example. As a result, losses at high frequencies cumulatively influence the signal waveforms of the differential input signal, and the signal waveforms of the optical signal generated in response to the differential input signal may be significantly deteriorated.

In a case where the differential input signal is a multi-value signal, such as a PAM-4 signal, and the laser driver 22 according to an embodiment of the present invention generates a driving signal for driving the laser diode 23 through linear amplification, the laser driver 22 corrects the frequency characteristics upon electro-optical conversion at the laser diode 23 by changing the frequency characteristics of the gain of the differential amplifier 33 to improve the waveform quality of the optical signal.

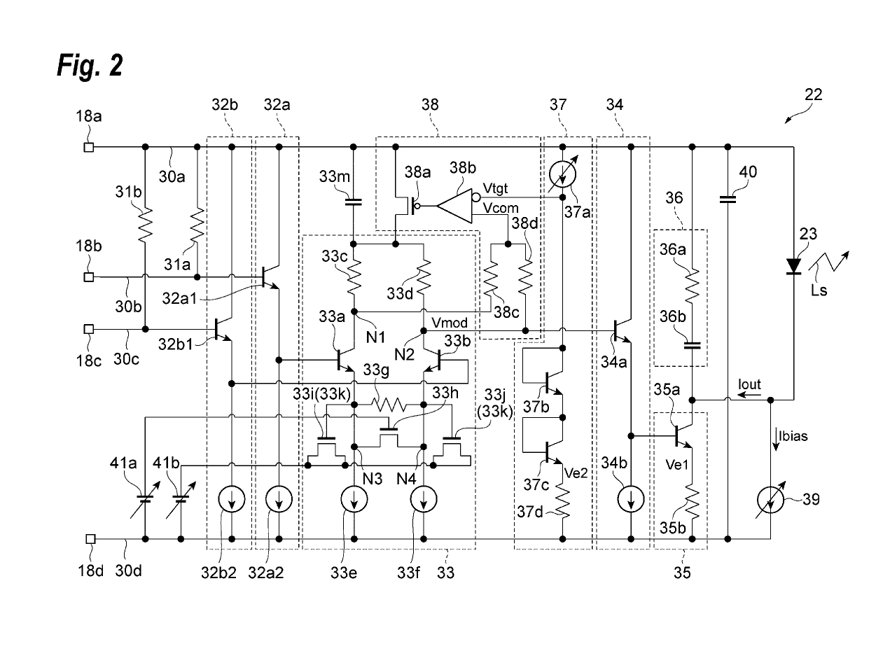

The circuit configuration of the laser driver 22 according to an embodiment of the present invention is described with reference to FIG. 2. FIG. 2 is a schematic diagram of the laser driver 22 shown in FIG. 1. As illustrated in FIG. 2, the laser driver 22 includes a pair of termination resistors 31a and 31b, a pair of input-side emitter followers 32a and 32b, the differential amplifier 33, an output-side emitter follower 34, the driver 35, a filter 36, the target potential circuit 37, the adjusting circuit 38, a bias current source 39, and a capacitor 40.

The input-side emitter followers 32a and 32b are electrically coupled to the terminals 18b and 18c through a positive-phase signal line 30b and a negative-phase signal line 30c respectively. The input-side emitter followers 32a and 32b receive a differential output signal of the CDR circuit 15 through the terminals 18b and 18c and outputs the differential output signal to the differential amplifier 33 with a low output impedance. Accordingly, the input-side emitter followers 32a and 32b separate the capacitive load of the differential amplifier 33 from the input terminals of the input-side emitter followers 32a and 32b and suppress electrical reflection of high frequency components of the positive-phase input signal INP and the negative-phase input signal INN. The input-side emitter follower 32a includes a transistor 32a1 and a constant current source 32a2, for example. The transistor 32a1 may be an NPN-type bipolar transistor, for example. The control terminal (base) of the transistor 32a1 is connected to the terminal 18b through the positive-phase signal line 30b. One of the current terminals (collector) of the transistor 32a1 is connected to a power line 30a. The other current terminal (emitter) of the transistor 32a1 is connected to one end of the constant current source 32a2. The other end of the constant current source 32a2 is connected to the terminal 18d through a reference potential line 30d. Similarly, the input-side emitter follower 32b includes a transistor 32b1 and a constant current source 32b2. The transistor 32b1 may be an NPN-type bipolar transistor, for example. The control terminal (base) of the transistor 32b1 is connected to the terminal 18c through the negative-phase signal line 30c. One of the current terminals (collector) of the transistor 32b1 is connected to the power line 30a. The other current terminal (emitter) of the transistor 32b1 is connected to one end of the constant current source 32b2. The other end of the constant current source 32b2 is connected to the terminal 18d through the reference potential line 30d.

The termination resistor 31a is connected between the power line 30a and the positive-phase signal line 30b. The termination resistor 31a consumes electric energy of the positive-phase input signal INP transmitted through the positive-phase signal line 30b and suppresses reflection of high frequency components of the positive-phase input signal INP on the CDR circuit 15. The termination resistor 31b is connected between the power line 30a and the negative-phase signal line 30c. The termination resistor 31b consumes electric energy of the negative-phase input signal INN transmitted through the negative-phase signal line 30c and suppresses reflection of high frequency components of the negative-phase input signal INN on the CDR circuit 15. The termination resistors 31a and 31b have a resistance of about 50Ω, for example, for matching with the characteristic impedance of the transmission line 21 formed on the PCB 12 and on the FPC 13.

The differential amplifier 33 receives the differential input signal (positive-phase input signal INP and negative-phase input signal INN) through the input-side emitter followers 32a and 32b and generates a driving signal Vmod from a signal obtained by performing linear amplification on the differential input signal. The differential amplifier 33 includes a series circuit (first series circuit) including a resistor 33c, a transistor 33a, and a current source 33e that are connected in series to each other in this order and a series circuit (second series circuit) including a resistor 33d, a transistor 33b, and a current source 33f that are connected in series to each other in this order. The first series circuit and the second series circuit are connected in parallel to each other. The current sources 33e and 33f supply source currents to the series circuits to which the current sources 33e and 33f belong respectively. The source current supplied by the current source 33e is equal to the source current supplied by the current source 33f. The transistors 33a and 33b may be NPN-type bipolar transistors, for example.

In more detail, the control terminal (base) of the transistor 33a is connected to the output terminal of the input-side emitter follower 32a, the output terminal corresponding to the connection point of the other current terminal (emitter) of the transistor 32a1 and the constant current source 32a2. The control terminal (base) of the transistor 33a receives the positive-phase input signal INP through the input-side emitter follower 32a. The control terminal (base) of the transistor 33b is connected to the output terminal of the input-side emitter follower 32b, the output terminal corresponding to the connection point of the other current terminal (emitter) of the transistor 32b1 and the constant current source 32b2. The control terminal (base) of the transistor 33b receives the negative-phase input signal INN through the input-side emitter follower 32b. One of the current terminals (collector) of the transistor 33a is connected to one end of the resistor 33c. One of the current terminals (collector) of the transistor 33b is connected to one end of the resistor 33d. The other end of the resistor 33c is connected to the other end of the resistor 33d. This common connection point is connected to the power line 30a through an under-mentioned variable resistor (transistor 38a) of the adjusting circuit 38. Note that the resistances of the resistors 33c and 33d are equal to each other. A bypass capacitor 33m is further connected in parallel to the transistor 38a between the connection point of the other end of the resistor 33c and the other end of the resistor 33d and the power line 30a. Accordingly, the other end of the resistor 33c and the other end of the resistor 33d are grounded to the power line 30a relative to an alternating current (AC) signal, especially a high frequency signal. The other current terminal (emitter) of the transistor 33a and that of the transistor 33b are connected to one end of the current source 33e and that of the current source 33f respectively and are connected to each other through a fixed resistor 33g. The other end of the current source 33e and that of the current source 33f are connected to the reference potential line 30d.

The differential amplifier 33 outputs the driving signal Vmod generated as a result of a voltage drop at the resistor 33d. The output terminal of the differential amplifier 33 corresponds to the connection point (node N2) of one of the current terminals (collector) of the transistor 33b and the resistor 33d. Note that a complementary signal having a phase different from the phase of the driving signal Vmod by 180° is generated at the connection point (node N1) of one of the current terminals (collector) of the transistor 33a and the resistor 33c as a result of a voltage drop at the resistor 33c.

The differential amplifier 33 further includes a parallel circuit including a variable resistor 33h and a variable capacitance element 33k that are connected in parallel to each other. One end of the parallel circuit is connected to the connection point (node N3) of the transistor 33a (first transistor) and the current source 33e (first current source) of the first series circuit. The other end of the parallel circuit is connected to the connection point (node N4) of the transistor 33b (second transistor) and the current source 33f (second current source) of the second series circuit. The variable resistor 33h is suitably constituted by a field-effect transistor (FET), for example. In this case, the resistance between the two current terminals (drain-source) of the FET is set to any value within an appropriate range in accordance with a voltage (first voltage) applied to the control terminal (gate) of the FET. In this embodiment, the control terminal of the FET is connected to a variable voltage source 41a. Note that the source of the FET may be connected to the node N3 and the drain of the FET may be connected to the node N4, and vice versa.

The variable capacitance element 33k is connected in parallel to the variable resistor 33h between the node N3 and the node N4. The variable capacitance element 33k is suitably constituted by a varactor diode, for example. The variable capacitance element 33k may include two varactor diodes, and one end of one of the varactor diodes and one end of the other varactor diode may be connected to each other, for example. In this case, the static capacitance of each of the varactor diodes is set to any value within an appropriate range in accordance with a voltage (second voltage) applied to the connection point at which the one end of one of the varactor diodes and the one end of the other varactor diode are connected to each other. The static capacitance of the variable capacitance element 33k is the sum of the capacitances of the two varactor diodes.

The variable capacitance element 33k of this embodiment is configured so that two FETs 33i and 33j act as varactor diodes. Specifically, the gate of the FET 33i is connected to the node N3, and the source and the drain of the FET 33i are connected in common to a variable voltage source 41b. Similarly, the gate of the FET 33j is connected to the node N4, and the source and the drain of the FET 33j are connected in common to the variable voltage source 41b. The capacitance between the node N3 and the node N4 can be changed by adjusting the voltage (second voltage) supplied by the variable voltage source 41b. In this way, dependence of gate-source capacitance of an FET on gate-source voltage may be used as a varactor diode.

The output-side emitter follower 34 receives the driving signal Vmod with a high input impedance and outputs the driving signal Vmod with a low output impedance. In other words, the output-side emitter follower 34 performs impedance conversion. Accordingly, the output-side emitter follower 34 separates the capacitive load of the driver 35 from the output terminal of the differential amplifier 33. The output-side emitter follower 34 includes a transistor 34a and a constant current source 34b, for example. The transistor 34a is an NPN-type bipolar transistor, for example. The control terminal (base) of the transistor 34a is connected to the output terminal of the differential amplifier 33, namely, to the node N2. One of the current terminals (collector) of the transistor 34a is connected to the power line 30a, and the other current terminal (emitter) of the transistor 34a is connected to one end of the constant current source 34b. The other end of the constant current source 34b is connected to the reference potential line 30d.

The driver 35 receives the driving signal Vmod through the output-side emitter follower 34, converts the driving signal Vmod into a driving current (output current), and makes the driving current flow through the laser diode 23. Therefore, the output terminal of the driver 35 is connected to the cathode of the laser diode 23. That is, the driver 35 is connected in series to the laser diode 23. The driver 35 includes a driving transistor 35a and a resistor 35b, for example. The driving signal Vmod is received through the control terminal (base) of the driving transistor 35a, and the driving current (output current) to be output from one of the current terminals (collector) is changed in response to the driving signal Vmod. The driving current flows from the cathode of the laser diode 23 into the output terminal of the driver 35, the output terminal corresponding to the collector of the driving transistor 35a. That is, the driving transistor 35a causes the driving current to flow so as to pull the driving current from the laser diode 23. The resistor 35b is connected in series to the driving transistor 35a and provides a negative feedback to the driving transistor 35a. The driving transistor 35a is an NPN-type bipolar transistor, for example. In this case, the control terminal (base) of the driving transistor 35a is connected to the output terminal of the output-side emitter follower 34, the output terminal corresponding to the connection point of the other current terminal (emitter) of the transistor 34a and the constant current source 34b. One of the current terminals (collector) of the driving transistor 35a, namely, the output terminal of the driver 35, is connected to the cathode of the laser diode 23. The other current terminal (emitter) of the driving transistor 35a is connected to the reference potential line 30d through the resistor 35b. The resistor 35b linearizes the input/output characteristics of the driving transistor 35a when a voltage drop produced by the driving current flowing through the resistor 35b provides a negative feedback to the base-emitter voltage of the driving transistor 35a.

The filter 36 is connected in parallel to the laser diode 23 and is connected in series to the driver 35. The filter 36 includes a resistor 36a and a capacitor 36b, for example. One end of the resistor 36a is connected to the power line 30a. The other end of the resistor 36a is connected to one of the electrodes of the capacitor 36b. The other electrode of the capacitor 36b is connected to the connection point (output terminal of the driver 35) of the cathode of the laser diode 23 and one of the current terminals (collector) of the driving transistor 35a. Note that the filter 36 may be configured such that the positions of the aforementioned resistor 36a and the capacitor 36b are interchanged. The filter 36 is often used for damping some frequency dependence of gain of the laser driver 22.

The bias current source 39 is connected to the cathode of the laser diode 23 and is connected in parallel to the driver 35. The bias current source 39 supplies a direct bias current to the laser diode 23. When the magnitude of the bias current is represented by Ibias and the magnitude of the driving current (output current) of the driver 35 is represented by Iout, the magnitude of the current that flows through the laser diode 23 is represented by Ibias+Iout.

One of the electrodes of the capacitor 40 is connected to the power line 30a. The other electrode of the capacitor 40 is connected to the reference potential line 30d. The capacitor 40 forms a path for returning high frequency components of the driving current flowing through the driver 35 and the laser diode 23 from the reference potential line 30d to the power line 30a. Accordingly, the capacitor 40 provide a return path for the driving current.

The target potential circuit 37 generates a target potential Vtgt. The target potential circuit 37 includes a variable current source 37a, a diode-connection transistor 37b that replicates the transistor 34a, a diode-connection transistor 37c that replicates the driving transistor 35a, and a resistor 37d that replicates the resistor 35b, for example. The variable current source 37a, the diode-connection transistor 37b, the diode-connection transistor 37c, and the resistor 37d are connected in series in this order between the power line 30a and the reference potential line 30d. The target potential Vtgt is generated by a sum of the voltage drops at the diode-connection transistors 37b and 37c and at the resistor 37d with reference to the reference potential (GND). The target potential Vtgt is output from the connection point of the variable current source 37a and the transistor 37b. It is preferable that the diode-connection transistor 37b have electrical characteristics identical to those of the transistor 34a. Similarly, it is preferable that the diode-connected transistor 37c have electrical characteristics identical to those of the driving transistor 35a. The electrical characteristics mentioned here specifically mean basic electrical characteristics of bipolar transistors, such as the base current (base-emitter current) relative to the base voltage (base-emitter voltage) and the collector current relative to the collector voltage when a specific base current (base-emitter current) is flowing. It is preferable that the diode-connected transistor 37b and the transistor 34a have substantially identical electrical characteristics in a case where the sizes thereof are equal to each other, for example. However, the sizes of the respective transistors when the transistors are actually used may be determined in accordance with the magnitude of the current supplied by the variable current source 37a as described below. The state where a transistor replicates another transistor means that the characteristics of the two transistors are identical or similar to each other (for example, there may be a proportional relationship between the transistors). As a result, the voltage drop of the transistor 37b may be set substantially equal to a voltage drop of the transistor 34a.

The adjusting circuit 38 includes the variable resistor (transistor) 38a, an operational amplifier 38b, and resistors 38c and 38d. The transistor 38a is an example of the variable resistor connected between the differential amplifier 33 and the power line 30a. The transistor 38a is a p-channel metal-oxide semiconductor (pMOS) FET, for example. Accordingly, such a simple configuration enables the variable resistor which resistance is changed in response to a control signal. The control terminal (gate) of the transistor 38a is connected to the output of the operational amplifier 38b. One of the current terminals (source) of the transistor 38a is connected to the power line 30a, and the other current terminal (drain) of the transistor 38a is connected to the point at which the other ends of the pair of the resistors 33c and 33d of the differential amplifier 33 are connected to each other. The resistance between one of the current terminals (drain) of the transistor 38a and the other current terminal (source) thereof changes in accordance with the output voltage from the operational amplifier 38b, which is applied the control terminal (gate) of the transistor 38a.

The resistors 38c and 38d constitute a detecting circuit that detects the center potential between the collector potential of the transistor 33a and the collector potential of the transistor 33b. One end of the resistor 38c is connected to one end of the resistor 38d, and the connection point at which the one end of the resistor 38c and the one end of the resistor 38d is connected to each other and also connected to the non-inverting input terminal of the operational amplifier 38b. The other end of the resistor 38c is connected to the connection point (node N1) of the transistor 33a and the resistor 33c. The potential at the other end of the resistor 38c is equal to the potential at one of the current terminals (collector) of the transistor 33a. The other end of the resistor 38d is connected to the connection point (node N2) of the transistor 33b and the resistor 33d. The potential at the other end of the resistor 38d is equal to the potential at one of the current terminals (collector) of the transistor 33b. When the resistance of the resistor 38c is made identical to the resistance of the resistor 38d, the potential in the center between the collector potential of the transistor 33a and the collector potential of the transistor 33b (that is, a potential Vcom that is in the average potential between the high level and the low level of the driving signal Vmod) is input to the non-inverting input terminal of the operational amplifier 38b. This center potential Vcom corresponds to the average potential of the differential signal output to the node N1 and to the node N2 and remains constant relative to time, because the center potential at the connection point at which the one end of the resistor 38c and the one end of the resistor 38d are connected always provides the average potential of the respective potentials at the node N1 and N2. Here, the center potential Vcom is called a common potential. Even in a case where the differential input signal is a PAM-4 signal described below, when neighboring symbols (logic levels) are equally spaced and the occurrence factors of the respective symbols are equal to one another, the center potential (common potential) is equal to the average potential of the peak value (maximum symbol) and the bottom value (minimum symbol) of the driving signal Vmod. The resistors 38c and 38d have a value of 10 kΩ, for example. The target potential Vtgt is input to the inverting input terminal of the operational amplifier 38b. With such a circuit configuration, the adjusting circuit 38 controls the resistance between the two current terminals (drain and source) of the transistor 38a so that the common potential Vcom and the target potential Vtgt input to the operational amplifier 38b become identical to each other. The open-loop gain of typical operational amplifiers is 10⁵ or more, and the adjusting circuit 38 can be configured so that the common potential Vcom is substantially equal to the target potential Vtgt upon implementation. It is preferable that the target potential Vtgt be set so that the bottom value of the driving signal Vmod is higher than the base-emitter voltage of the driving transistor 35a.

The operation of the aforementioned laser driver 22 of this embodiment is described. Note that, in the following description, it is assumed that a PAM-4 signal is input to the optical transmitter 1A from outside the optical transmitter 1A as the differential input signal (positive-phase input signal INP and negative-phase input signal INN). A PAM-4 signal transfers among four levels having equal intervals, and thus transmits two bits of information in a single modulating operation. A PAM-4 signal is an example of a multi-value modulation signal.

The differential input signal (positive-phase input signal INP and negative-phase input signal INN) input from outside the optical transmitter 1A transits the CDR circuit 15 and the coupling capacitors 16a and 16b and is thereafter input to the input-side emitter followers 32a and 32h of the laser driver 22. Although the current amplification factors at the input-side emitter followers 32a and 32b depend on the currents respectively supplied by the constant current sources 32a2 and 32b2, the voltage amplification factors are always equal to 1 approximately. Therefore, the input-side emitter follower 32a shifts the positive-phase input signal INP by the base-emitter voltage of the transistor 32a1 without changing the amplitude and outputs the level-shifted positive-phase input signal INP. Similarly, the input-side emitter follower 32b shifts the negative-phase input signal INN by the base-emitter voltage of the transistor 32b1 without changing the amplitude and outputs the level-shifted negative-phase input signal INN. Accordingly, the input-side emitter followers 32a and 32b shift the average potential of the differential input signal and input the shifted differential input signal to the differential amplifier 33. At this time, the voltage amplitude of the differential input signal does not change; however, the output impedance can be decreased by increasing the currents supplied by the constant current sources 32a2 and 32b2. As a result, the low output impedance helps to drive the differential amplifier 33 fast.

In the differential amplifier 33, the level-shifted positive-phase input signal INP is input to the control terminal (base) of the transistor 33a, and the level-shifted negative-phase input signal INN is input to the control terminal (base) of the transistor 33b. At the transistors 33a and 33b, the sum of the source currents supplied by the current sources 33e and 33f is divided into the collector currents of the respective transistors in accordance with the voltage difference between the signals respectively input to the control terminals of the transistors 33a and 33b, where base currents of the transistors 33a and 33b are regarded as negligible. That is, when the voltage of the positive-phase input signal INP is higher than the voltage of the negative-phase input signal INN, the collector current of the transistor 33a is larger than the collector current of the transistor 33b, and when the voltage of the positive-phase input signal INP is lower than the voltage of the negative-phase input signal INN, the collector current of the transistor 33a is smaller than the collector current of the transistor 33b. When the voltage of the positive-phase input signal INP is equal to the voltage of the negative-phase input signal INN, the collector current of the transistor 33a is substantially equal to the collector current of the transistor 33b. Accordingly, the collector current of the transistor 33a and the collector current of the transistor 33b complementarily change in accordance with the voltage difference between the positive-phase input signal INP and the negative-phase input signal INN.

The collector current of the transistor 33a produces a voltage drop at the resistor 33c and decreases the potential at the node N1. The collector current of the transistor 33b produces a voltage drop at the resistor 33d and decreases the potential at the node N2. Therefore, when the voltage of the positive-phase input signal INP is higher than the voltage of the negative-phase input signal INN, the voltage at the node N2 becomes higher than the voltage at the node N1, and when the voltage of the positive-phase input signal INP is lower than the voltage of the negative-phase input signal INN, the voltage at the node N2 becomes lower than the voltage at the node N1. Accordingly, the potential at the node N2 repeatedly rises and falls in response to the differential input signal, and the signal logic is identical to the signal logic of the positive-phase input signal INP. That is, when the voltage of the positive-phase input signal INP is high, the potential at the node N2 becomes high, and when the voltage of the positive-phase input signal INP is low, the voltage at the node N2 becomes low. The same applies to the case where the differential input signal has two levels as in the case of a non-return-to-zero (NRZ) signal and to the case where the differential input signal has four levels as in the case of a PAM-4 signal. The differential amplifier 33 outputs the voltage at the node N2 as the driving signal Vmod.

Note that, when the absolute value of the voltage difference between the positive-phase input signal INP and the negative-phase input signal INN is larger than a threshold value (for example, a value that corresponds to the input range of linear amplification), the collector current only flows through one of the transistors 33a and 33b and does not flow through the other. This is because the transistor receiving a potential higher than a potential of another transistor by the threshold value or more is turned on and the other transistor receiving a potential lower than a potential of the transistor by the threshold value or more is turned off. Hereafter, such operation is called limiting amplification. The transistors 33a and 33b complementarily operate such that, when one of the transistors is turned on, the other is turned off, and when one of the transistors is turned off, the other is turned on. This complementary operation is determined on the basis of the magnitude correlation between the potential of the positive-phase input signal INP and that of the negative-phase input signal INN. That is, when the voltage of the positive-phase input signal INP is sufficiently higher than the voltage of the negative-phase input signal INN, the transistor 33a is turned on and the transistor 33b is turned off. In contrast, when the voltage of the positive-phase input signal INP is lower than the voltage of the negative-phase input signal INN, the transistor 33a is turned off and the transistor 33b is turned on. When one of the transistors 33a and 33b is turned on and the other is turned off, the voltage difference between the node N1 and the node N2 is saturated to a constant value, and therefore, the relationship between the differential input signal and the output signal (driving signal) becomes nonlinear.

In this embodiment, the amplitude of the differential input signal (difference between the positive-phase input signal INP and the negative-phase input signal INN) is set so as to fall within the range of linear amplification of the differential amplifier 33. As a result, the amplitude of the driving signal Vmod has a magnitude proportional to the amplitude of the differential input signal. In the case where the differential input signal is a PAM-4 signal, the differential input signal has four logic levels (symbols) in the amplitude direction, and therefore, the difference between any two of the four logic levels comes in three kinds. That is, there exist the amplitude (which is the maximum value of the amplitude) when the signal transfers between the minimum symbol (bottom value) and the maximum symbol (peak value), the amplitude (which is the minimum value of the amplitude) when the signal transfers between neighboring two symbols, and the amplitude (which has an intermediate value between the maximum value of the amplitude and the minimum value of the amplitude) when the signal transfers between a certain symbol and a symbol spaced apart from the certain symbol by two symbols. When the differential amplifier 33 performs linear amplification, the three kinds of amplitudes are amplified by the same ratio (voltage amplification factor, or gain), and the result is output as the driving signal Vmod.

The driving signal Vmod output from the differential amplifier 33 is input to the output-side emitter follower 34. Although the current amplification factor at the output-side emitter follower 34 depends on the current supplied by the constant current source 34b, the voltage amplification factor (gain) is always equal to 1 approximately. Therefore, the output-side emitter follower 34 shifts the driving signal Vmod by the base-emitter voltage of the transistor 34a without changing the amplitude and outputs the driving signal Vmod.

The level-shifted driving signal Vmod is input to the control terminal (base) of the driving transistor 35a in the driver 35. The driving transistor 35a outputs the driving current Iout in accordance with the voltage input to the control terminal.

Increase in the potential of the driving signal Vmod causes increase in the collector current of the driving transistor 35a and also increase in the driving current Iout. Reversely, decrease in the potential of the driving signal Vmod causes decrease in the collector current of the driving transistor 35a and also decrease in the driving current Iout. The output terminal of the driver 35 corresponds to the collector of the driving transistor 35a and is connected to the cathode of the laser diode 23. Therefore, increase in the driving current Iout causes increase in the output power of the optical signal Ls output from the laser diode 23. Reversely, decrease in the driving current Iout causes decrease in the output power of the optical signal Ls output from the laser diode 23. When the logic level of the differential input signal is at the peak value (maximum symbol) among the four logic levels of the PAM-4 signal, for example, the logic level of the optical signal Ls is also at the peak value (maximum symbol) among the four logic levels defined for the optical signal Ls. When the logic level of the differential input signal is at the bottom value (minimum symbol) among the four logic levels of the PAM-4 signal, the logic level of the optical signal Ls is also at the bottom value (minimum symbol) among the four logic levels of the optical signals Ls. Regarding the remaining two intermediate values among the four logic levels of the PAM-4 signal, the lower logic level of the optical signal Ls corresponds to the lower logic level of the differential input signal, and the higher logic level of the optical signal Ls corresponds to the higher logic level of the differential input signal, Accordingly, in the laser driver 22, multi-value modulation is performed on the optical signal Ls to be output from the laser diode 23 in response to the differential input signal. Note that the driving signal Vmod input to the control terminal of the driving transistor 35a includes a voltage equal to or higher than half the maximum amplitude of the multi-value signal (which is equal to the difference between the maximum symbol and the minimum symbol) as a DC bias component so that the driving current Iout is not distorted. The DC bias component is set in accordance with the aforementioned common potential Vcom. Therefore, the DC bias component is adjusted in accordance with the target potential Vtgt as described above. It is preferable that the target potential Vtgt is set so that the bottom value of the driving signal Vmod is higher than the base-emitter voltage of the driving transistor 35a.

When the laser driver 22 drives the laser diode 23 as described above, the filter 36 suppresses high frequency components of the driving current Iout, which have frequencies equal to or higher than a cut-off frequency. That is, the filter 36 bypasses such high frequency components to thereby correct the frequency characteristics of the driving current Iout that flows through the laser diode 23 and shape the waveforms of optical output into an optimum form. The configuration of the filter 36 and the circuit constants of the capacitor, resistor, and so on of the filter 36 are determined by taking account of dynamic characteristics, such as the relaxation oscillation frequency of the laser diode 23.

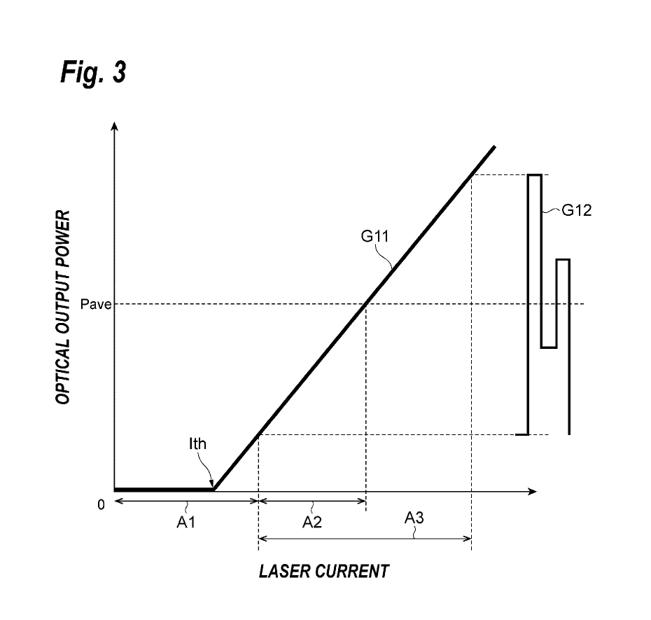

The graph G11 in FIG. 3 shows the relationship between the magnitude of the output current (laser current) that flows through the laser diode 23 and the amount of emission (optical output power) of the laser diode 23. The graph G12 in FIG. 3 represents an example of the waveform of optical output in the case where the differential input signal is a PAM-4 signal. As illustrated in FIG. 3, if the laser current does not exceed a threshold current Ith, emission of the laser diode 23 is quite small. If the laser current exceeds the threshold current Ith, laser oscillation is produced at the laser diode 23, and the emission of the laser diode 23 increases in proportion to the magnitude of the laser current. Note that FIG. 3 is a schematic diagram for explaining the driving operation of the laser diode 23 performed by the driver 35 and, in actuality, there may be a region in which emission is not proportional to the laser current.

Now, the three arrows A1 to A3 shown in FIG. 3 are described. The arrow A1 represents the bias current Ibias. The bias current Ibias is supplied by the bias current source 39, for example. The arrow A2 represents the DC bias component Iout(DC) of the driving current (output current) Iout. The DC bias component Iout(DC) corresponds to the aforementioned DC bias component. The arrow A3 represents the variable range (peak-to-peak value) of the modulation component Iout(mod) of the driving current (output current) Iout. Therefore, the driving current (output current) Iout output from the driver 35 is represented by Iout=Iout(DC)+Iout(mod). When the maximum amplitude (which corresponds to the difference between the peak value and the bottom value) of the modulation component Iout(mod) is represented by Imod, the variation range of the modulation component Iout(mod) is represented by the following formula:

−Imod/2≦Iout(mod)≦Imod/2.

Therefore, in order to prevent the waveforms of optical output from being distorted, the DC bias component Iout(DC) and the maximum amplitude Imod need to satisfy the following formula:

Iout(DC)≧Imod/2.

Note that, when the laser current is represented by ILD and the average of the optical output power P is represented by Pave, ILD and Pave are respectively represented by the following formulas:

ILD=Ibias+Iout=Ibias+Iout(DC)+Iout(mod), and

Pave=SLD×(Ibias+Iout(DC)−Ith),

where SLD represents the proportion coefficient (slope) ΔP/ΔILD of the graph G11.

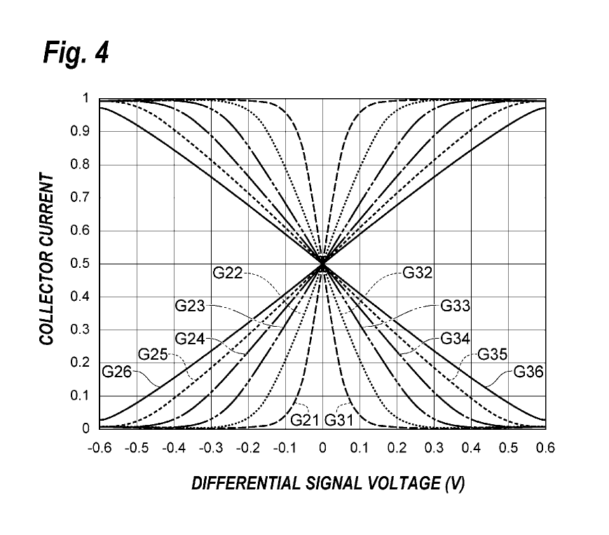

Now, the operation of the differential amplifier 33 of this embodiment is described in detail. As described above, the differential input signal (positive-phase input signal INP and the negative-phase input signal INN) input to the differential amplifier 33 is set so as to fall within the range of linear amplification of the differential amplifier 33. FIG. 4 includes graphs representing the relationships between the differential signal voltage and the collector currents of the transistors 33a and 33b. The differential signal voltage corresponds to the difference between the voltage of the positive-phase input signal INP and the voltage of the negative-phase input signal INN. The collector currents shown in FIG. 4 have values normalized on the basis of the maximum value, which corresponds to the sum of the respective source currents supplied by the current source 33e and 33f. Here, the combined resistance of the fixed resistor 33g and the variable resistor 33h is represented by REX, and the sum of the respective source currents supplied by the current sources 33e and 33f is represented by Id. The graphs G21 to G26 shown in FIG. 4 respectively represent the relationships between the collector current of the transistor 33a and the differential signal voltage in a case where VREX, which is the product of REX and Id, is 0 mV, 50 mV, 100 mV, 150 mV, 200 mV, and 250 mV. The graphs G31 to G36 respectively represent the relationships between the collector current of the transistor 33b and the differential signal voltage in the case where the product VREX is 0 mV, 50 mV, 100 mV, 150 mV, 200 mV, and 250 mV.

As represented in FIG. 4, increase in the product VREX causes decrease in the trans-conductance gain and decrease in a slope of the linear part (the amplification factor (gain) decreases). In other words, as the product VREX becomes larger, the amplification factor (gain) decreases, and as the product VREX becomes smaller, the amplification factor (gain) increases. For example, in a case where the amplitude of the differential signal voltage is set equal to or smaller than 600 mVppd, if the VREX of 150 mV or more is ensured, a stable linearity (with a back-off margin of 20% from the complete switching state) can be ensured. The amplitude of the differential signal voltage of 600 mVppd corresponds to the range between −0.3 V and +0.3 V on the horizontal axis in FIG. 4. The case where the product VREX is equal to 150 mV is shown by the graphs G24 and G34. Here, the graphs G24 and G34 each have a linear part (linear region) within the range of the differential signal voltage between −0.3 V and +0.3 V, and therefore, linearity is ensured. The complete switching state means that the collector current is saturated to 0 or 1, and the back-off margin represents the allowance of the linear region relative to the complete switching state.

Now, the frequency characteristics of the gain of the differential amplifier 33 are described The gain A(s) of the differential amplifier 33 is represented by Formula 1, where gm represents the trans-conductance of the transistors 33a and 33b, C_{C} represents the parasitic capacitance value parasitic to the node N2, R_{C} represents the resistance of the resistor 33c, R_{E} represents the resistance of the fixed resistor 33g, R_{EX} represents the combined resistance of the fixed resistor 33g and the variable resistor 33h, and C_{EX} equals to C_{E}/2 (C_{E} represents the capacitances of the varactor diodes 33i and 33j).

$$A ( s ) = \frac{gm}{{C}_{C}} \cdot \frac{s + \frac{1}{{R}_{EX} {C}_{EX}}}{( s + \frac{1}{{R}_{C} {C}_{C}} ) \cdot ( s + \frac{1 + gm {R}_{EX} / 2}{{R}_{EX} {C}_{EX}} )} \qquad ( 1 )$$

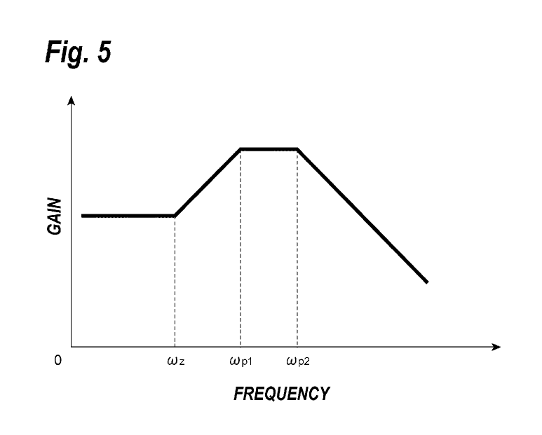

FIG. 5 is a graph representing the frequency characteristics of the gain of the differential amplifier 33 represented by Formula 1. In FIG. 5, the horizontal axis represents the frequency, and the vertical axis represents the gain of the differential amplifier 33. As shown in FIG. 5, the gain of the differential amplifier 33 remains constant up to the zero frequency ω_{z}. If the frequency exceeds the zero frequency ω_{z}, the gain rises. In the range between the first pole frequency ωₚ₁ (>ω_{z}) and the second pole frequency ωₚ₂ (>ωₚ₁), the gain remains constant again. If the frequency exceeds the second pole frequency ωₚ₂, the gain decreases as the frequency increases. This is because the impedance between the node N3 and the node N4 is determined on the basis of the combined resistor formed of the fixed resistor 33g and the variable resistor 33h in a low frequency region, and the impedance decreases due to the variable capacitance element 33k in a high frequency region. On the basis of Formula 1 above, the zero frequency ω_{z}, the first pole frequency ωₚ₁, and the second pole frequency ωₚ₂ are calculated using Formula 2 to Formula 4 below.

$$\begin{matrix}{ω}_{z} = \frac{1}{{R}_{EX} {C}_{EX}} & ( 2 ) \\ {ω}_{p 1} = \frac{1}{{R}_{C} {C}_{C}} & ( 3 ) \\ {ω}_{p 2} = \frac{1 + gm {R}_{EX} / 2}{{R}_{EX} {C}_{EX}} & ( 4 )\end{matrix}$$

When R_{C}=R_{EX}=75Ω, gm=0.125, C_{EX}=80 fF, and C_{C}=45 fF are assumed, for example, the results are ω_{z}=26.5 GHz, ωₚ₁=47 GHz, and ωₚ₂=150 GHz.

As evident from the above formulas, the second pole frequency ωₚ₂ is substantially proportional to the trans-conductance gm of the transistors 33a and 33b. Accordingly, when the current flowing through the transistors 33a and 33b increases, the trans-conductance gm increases. As a result, the second pole frequency ωₚ₂ increases, and the band of the gain of the differential amplifier 33 becomes wider. In contrast, when the current flowing through the transistors 33a and 33b decreases, the trans-conductance gm decreases. As a result, the second pole frequency ωₚ₂ decreases and approaches the zero-point frequency ω_{z}. Consequently, the band of the gain of the differential amplifier 33 becomes narrower.

Hereinafter, a case where the differential input signal is at the high level or at the low level is mainly described for easy understanding. However, it is not necessarily assumed that the differential input signal is a conventional binary signal like an NRZ signal. In the case where the differential signal is a PAM-4 signal, for example, if the maximum symbol (peak value) is assumed to be the high level and the minimum symbol (bottom value) is assumed to be the low level, the laser driver of this embodiment basically operates in a similar manner.

The collector current of the transistor 33b that constitutes the differential amplifier 33 decreases when the differential input signal is at the high level (that is, the negative-phase input signal INN is at the low level), and increases when the differential input signal is at the low level (that is, the negative-phase input signal INN is at the high level). Therefore, in the transistor 34a which receives the potential at the node N2 positioned at the collector of the transistor 33b, the base voltage increases when the differential input signal is at the high level, and the base voltage decreases when the differential input signal is at the low level.

Therefore, when the base voltage of the transistor 34a transfers to the high level (that is, in an emission state), the collector current of the transistor 33b decreases, and the trans-conductance gm of the transistor 33b decreases accordingly. As a result, the band of the gain A(s) of the differential amplifier 33 becomes narrower, and the base voltage of the transistor 34a relatively slowly changes. When the base voltage of the transistor 34a transfers to the low level (that is, in an extinction state), the collector current of the transistor 33b increases, and the trans-conductance gm of the transistor 33b increases accordingly. As a result, the band of the gain A(s) of the differential amplifier 33 becomes wider, and the base voltage of the transistor 34a relatively rapidly changes. Further, the peaking amplitude also increases, and therefore, an overshoot tends to be produced.

While the differential amplifier 33 has the characteristics as described above, the laser diode 23 has characteristics described below. The output terminal of the driver 35 of this embodiment is connected to the cathode of the laser diode 23. The anode of the laser diode 23 is connected to the power line 30a. In the laser diode 23, the relaxation oscillation frequency typically decreases as the forward current decreases. In other words, when the driving current (output current) Iout transfers to the low level, the relaxation oscillation frequency decreases and the band of the gain becomes narrower. When the driving current (output current) Iout transfers to the high level, the relaxation oscillation frequency increases and the band of the gain becomes wider.

Accordingly, in this embodiment, when the differential input signal transfers to the high level (that is, when the output current Iout transfers to the high level), the band of the gain of the differential amplifier 33 becomes narrower while the band of the gain of the laser diode 23 becomes wider. When the differential input signal transfers to the low level (that is, when the output current Iout transfers to the low level), the band of the gain of the differential amplifier 33 becomes wider while the band of the gain of the laser diode 23 becomes narrower. As a result, the frequency characteristics of the gain of the differential amplifier 33 and the frequency characteristics of the gain of the laser diode 23 are offset against each other, and the frequency characteristics upon a transfer to the high level can be balanced against the frequency characteristics upon a transfer to the low level. Consequently, the rising speed and the falling speed of the optical signal Ls are appropriately balanced against each other, and deterioration in the waveforms of the optical signal Ls may be suppressed.

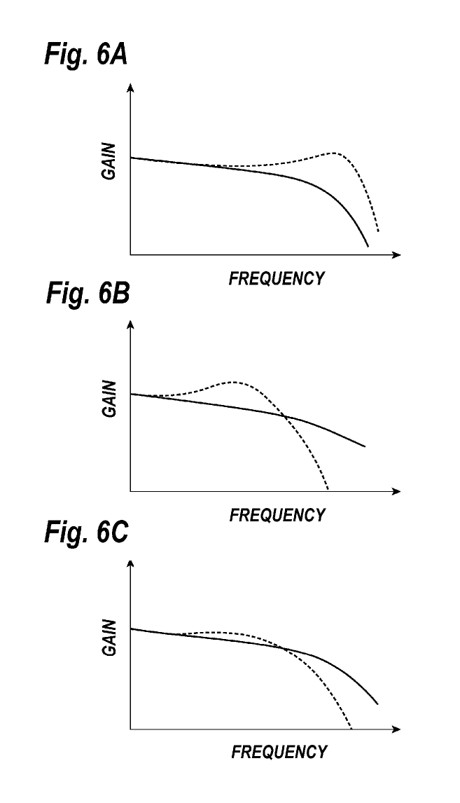

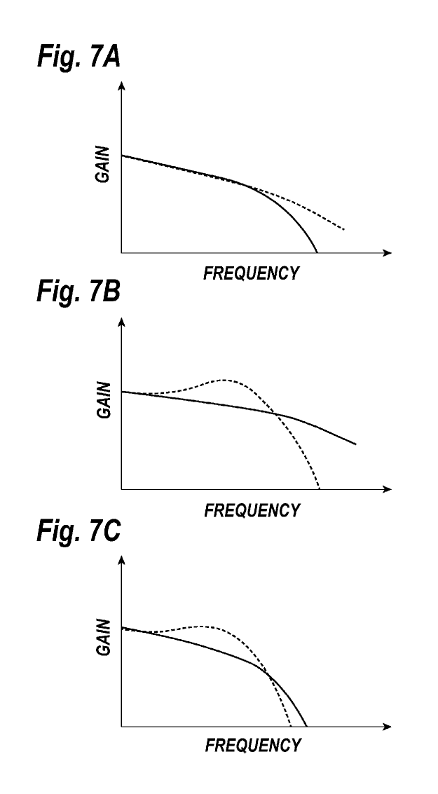

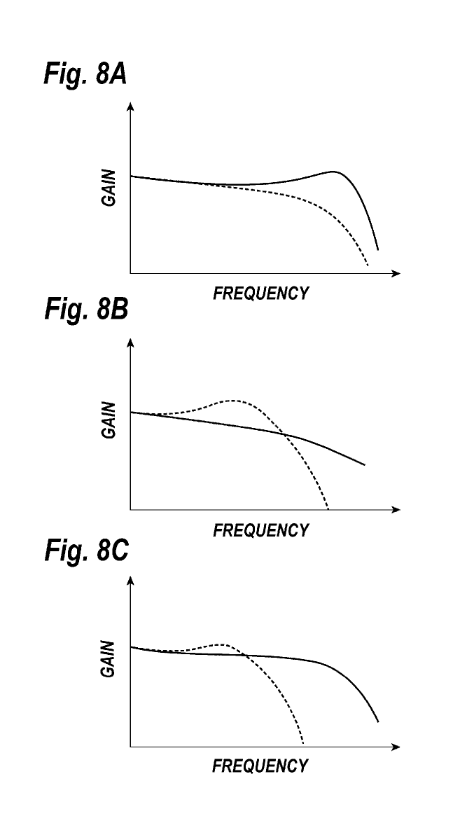

Now, the advantages of this embodiment described above are visually explained with reference to FIGS. 6A to 6C, FIGS. 7A to 7C, and FIGS. 8A to 8C. FIGS. 6A to 6C relate to the laser driver 22 of this embodiment. FIG. 6A shows the frequency characteristics of the gain of the differential amplifier 33 only, FIG. 6B shows the frequency characteristics of the gain of the laser diode 23 only, and FIG. 6C shows the frequency characteristics of the gain of the combination of the differential amplifier 33 and the laser diode 23. FIGS. 7A to 7C relate to a first comparative example. The first comparative example is different from this embodiment in that the fixed resistor 33g, the variable resistor 33h, and the variable capacitance element 33k are removed from the differential amplifier 33. FIG. 7A shows the frequency characteristics of the gain of the differential amplifier 33 only, FIG. 7B shows the frequency characteristics of the gain of the laser diode 23 only, and FIG. 7C shows the frequency characteristics of the gain of the combination of the differential amplifier 33 and the laser diode 23. FIGS. 8A to 8C relate to a second comparative example. The second comparative example is different from this embodiment in that the output terminal of the driver 35 is connected to the anode of the laser diode 23 (that is, the driver 35 and the laser diode 23 are connected in parallel to each other). FIG. 8A shows the frequency characteristics of the gain of the differential amplifier 33 only, FIG. 8B shows the frequency characteristics of the gain of the laser diode 23 only, and FIG. 8C shows the frequency characteristics of the gain of the combination of the differential amplifier 33 and the laser diode 23. Note that, in these diagrams, the solid line shows the characteristics upon a transfer to the high level (in the emission state, or the “ON” state), and the broken line shows the characteristics upon a transfer to the low level (in the extinction state, or the “OFF” state).

In the laser driver 22 of this embodiment, the differential amplifier 33 includes the fixed resistor 33g, the variable resistor 33h, and the variable capacitance element 33k as described above. As a result, peaking is produced in a high frequency region both in the emission state and in the extinction state, and the band of the gain is wide, as shown in FIG. 6A. For the emission state (the solid line) in FIG. 6A, the peaking effect does not produce a bump like the extinction state (the broken line) but enhances the band of the gain in comparison with the first comparable example (FIG. 7A). Therefore, the peaking effect due to the fixed resistor 33g, the variable resistor 33h, and the variable capacitance element 33k does not always produce a bump but often improve the frequency characteristics of the gain. Large peaking and wideband characteristics are obtained specifically in the extinction state. As described above, in the laser diode 23, typically, the relaxation oscillation frequency increases and the peaking amplitude decreases as the laser current increases. Therefore, in the case where the output terminal of the driver 35 is connected to the cathode of the laser diode 23, the band is wider and the peaking is lower in the emission state than in the extinction state, as shown in FIG. 6B. Accordingly, in the case where the differential amplifier 33 and the laser diode 23 are combined, the comprehensive frequency characteristics are such that the frequency characteristics of the differential amplifier 33 and the frequency characteristics of the laser diode 23 are offset and balanced against each other both in the emission state and in the extinction state, as shown in FIG. 6C. Therefore, the difference in the band in the emission state and in the extinction state may be reduced. Note that, in actuality, the band is slightly narrower in the extinction state than in the emission state.

In contrast, in the first comparative example, peaking is not produced in a high frequency region. Therefore, the band becomes wider as a larger amount of current flows through the transistor 33b. As a result, the band is wide in the extinction state and is narrow in the emission state, as shown in FIG. 7A. However, when compared to FIG. 6A, the band is narrower both in the emission state and in the extinction state. The characteristics of the laser diode 23 shown in FIG. 7B are identical to the characteristics shown in FIG. 6B. Therefore, in the case where the differential amplifier 33 and the laser diode 23 are combined, the comprehensive frequency characteristics are such that the band is narrower both in the emission state and in the extinction state, as shown in FIG. 7C, compared to the frequency characteristics shown in FIG. 6C.

In the second comparative example, peaking is produced in a high frequency region both in the emission state and in the extinction state, as illustrated in FIG. 8A, and the band of the gain is wide. Large peaking and wideband characteristics are obtained specifically in the emission state. The frequency characteristics of the laser diode 23 illustrated in FIG. 8B are identical to the frequency characteristics shown in FIG. 6B. Therefore, in the case where the differential amplifier 33 and the laser diode 23 are combined, the comprehensive frequency characteristics are such that the band is considerably wide in the emission state and is narrow in the extinction state, as shown in FIG. 8C. Accordingly, the difference in the band in the emission state and in the extinction state considerably increases compared to this embodiment (FIG. 6C). That is, the band in the emission state and that in the extinction state are poorly balanced, and the signal waveforms of the optical signal is restricted by the poorer characteristics and is deteriorated.

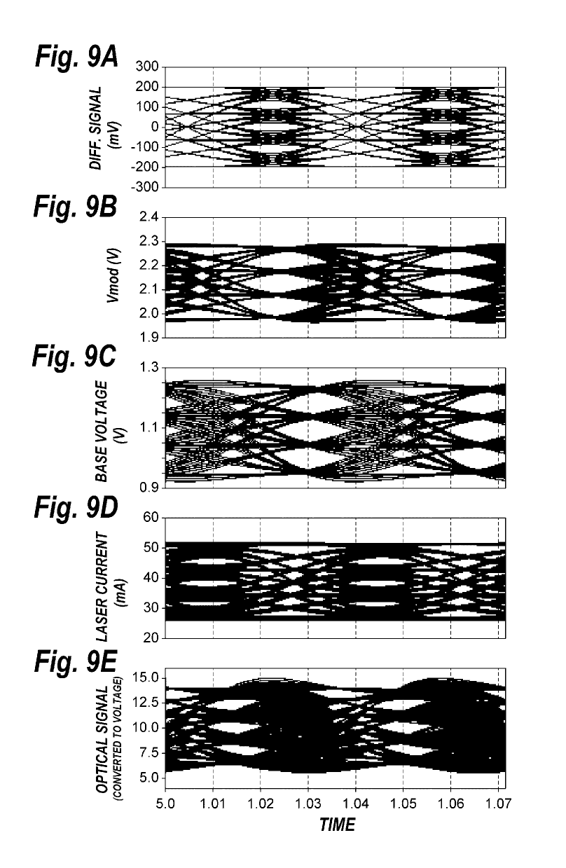

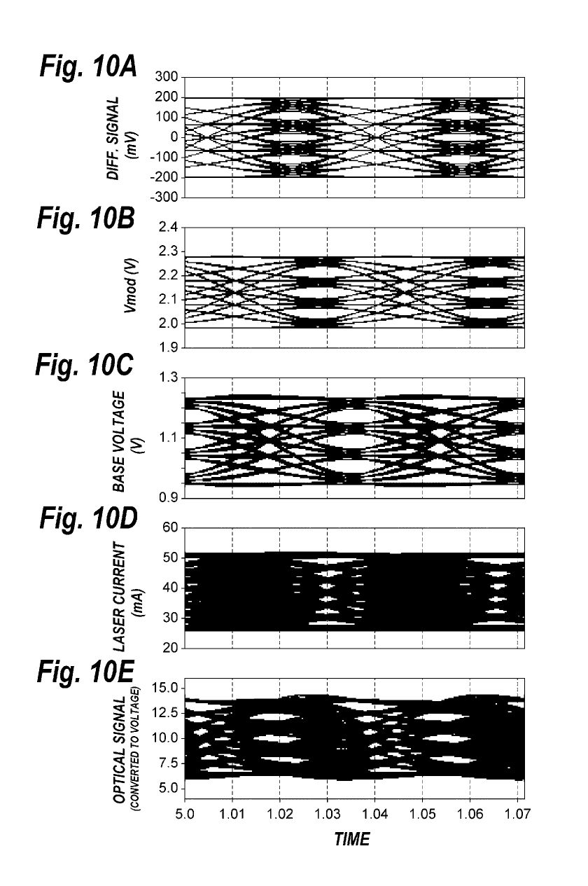

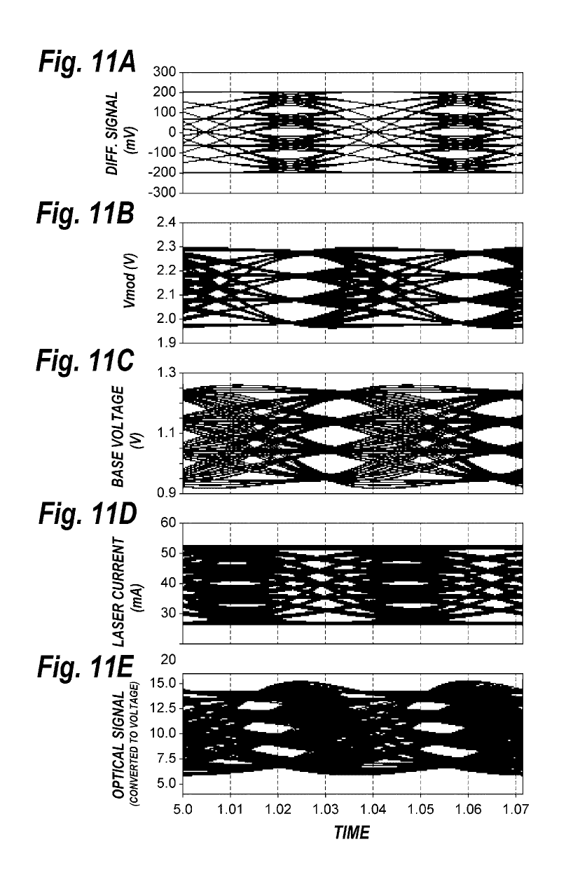

Subsequently, the advantages of this embodiment described above are explained with reference to the signal waveforms (eye-patterns) shown in FIGS. 9A to 9E, FIGS. 10A to 10E, and FIGS. 11A to 11E. FIGS. 9A to 9E relate to the laser driver 22 of this embodiment, FIGS. 10A to 10E relate to the aforementioned first comparative example, and FIGS. 11A to 11E relate to the aforementioned second comparative example. Each set of five diagrams are diagrams that respectively represent the eye-pattern of the differential input signal (PAM-4 signal), that of the driving signal Vmod output from the differential amplifier 33, that of the base voltage of the driving transistor 35a, that of the laser current ILD, and that of the optical signal Ls (where the vertical axis represents the voltage value corresponding to the optical output power).

As described above, the eye-openings of the differential input signal input to the laser driver 22 are deteriorated due to losses at high frequencies produced in the PCB 12, the FPC 13, the coupling capacitors 16a and 16b, and so on. As represented in FIG. 10B, in the first comparative example, the driving signal Vmod output from the differential amplifier 33 has a shape similar to that of the differential input signal. This is because the fixed resistor 33g, the variable resistor 33h, and the variable capacitance element 33k are not included in the differential amplifier 33 in the first comparative example, and the first comparative example does not have the advantage of these elements that widen the band of the gain. Further, as shown in FIG. 10C, the base voltage of the driving transistor 35a has a shape similar to that of the differential input signal. As a result, the fast operation is restricted by the band, which is an electrical characteristic of the laser diode 23, and the eye-openings of the laser current ILD represented in FIG. 10D collapse. Note that, the optical signal output by the laser diode 23 that is driven by the laser current ILD barely has eye-openings, as represented in FIG. 10E. This is because the band is widened by relaxation oscillation produced by the laser diode 23 when an electrical signal is converted into an optical signal.

In the second comparative example, the differential amplifier 33 includes the fixed resistor 33g, the variable resistor 33h, and the variable capacitance element 33k, and therefore, the driving signal Vmod output from the differential amplifier 33 has significantly improved eye-openings, as shown in FIG. 11B. The base voltage of the driving transistor 35a is similarly improved as in the driving signal Vmod, as shown in FIG. 11C. However, the driver 35 is connected to the anode of the laser diode 23. Therefore, in the waveforms of the laser current ILD, a transfer from the extinction state to the emission state (rising) is relatively fast, and a transfer from the emission state to the extinction state (falling) is relatively slow, as represented in FIG. 11D. As a result, the optical signal has a waveform that is asymmetric about the center level of the amplitude such that rising is fast and falling is slow, as shown in FIG. 11E. That is, the three eye-openings lying in the vertical axis direction are shifted from one another in the horizontal axis direction.

Normally, in a case where a PAM-4 signal is received and the logic levels (symbols) are discriminated by a receiving circuit, discrimination is performed without changing the phase for each symbol. Therefore, discrimination of the symbols is performed at the same phase (the same instant) for all of the symbols. Accordingly, it is preferable that the three eye-openings lying in the vertical axis direction not be shifted from one another in the horizontal axis direction and that the centers of the three eye-openings be aligned parallel to the vertical axis. If the eye-openings of neighboring symbols are shifted from one another in the horizontal axis direction as shown in FIG. 11E, even if the phase at which discrimination is performed is adjusted so as to obtain the best error rate for a specific eye-opening, discrimination on the remaining eye-openings is performed at the phase apart from the centers of the remaining eye-openings, resulting in a worsened error rate. As a result, an issue in which the comprehensive error rate is worsened arises. This is caused by the fact that the positions of the three eye-openings lying in the vertical axis direction are not aligned in the horizontal axis (time) direction to the same instant.

In the laser driver 22 of this embodiment, the waveform of the driving signal Vmod is significantly improved compared to the first comparative example, as shown in FIG. 9B. Further, the driver 35 is connected to the cathode of the laser diode 23, and therefore, a rapid transfer from the extinction state to the emission state (fast rising) and a slow transfer from the emission state to the extinction state (slow falling) are improved compared to the second comparative example, as shown in FIG. 9D. As a result, the imbalance between the rising time and the falling time is improved in the waveform of the optical signal, as shown in FIG. 9E, and the mutual shifts, in the horizontal axis direction, of the three eye-openings lying in the vertical axis direction are reduced. Accordingly, in the optical signal shown in FIG. 9E, the error rate in discrimination of the symbols of the PAM-4 signal performed by the receiving circuit is improved compared to the optical signals shown in FIG. 10E and FIG. 11E.

As explained above, the laser driver 22 of this embodiment may compensate the frequency characteristics upon electro-optical conversion at the laser diode 23 and reduce the imbalance between the rising time and the falling time of the optical signal Ls by adjusting the frequency characteristics of the gain of the differential amplifier 33. Accordingly, a deterioration in the waveforms of the optical signal Ls due to losses at high frequencies produced in the PCB 12, the FPC 13, the coupling capacitors 16a and 16b, and so on may be reduced.

As described above, in the laser driver 22 of this embodiment, the amplitude of the driving signal Vmod is substantially proportional to the amplitude of the differential input signal as a result of linear amplification by the differential amplifier 33. Accordingly, in a case where the differential input signal is a multi-value signal (a PAM-4 signal, for example), the laser diode 23 can be suitably driven by equally amplifying the distance (amplitude) between neighboring symbols of the multi-value signal.

As described above, in the laser driver 22 of this embodiment, as the product VREX of the impedance of the variable resistor 33h provided in the differential amplifier 33 and the sum of the respective source currents supplied by the current sources 33e and 33f provided in the differential amplifier 33 increases, the trans-conductance gain of the transistors 33a and 33b decreases, and the amplification factor (gain) decreases. In contrast, as the product VREX decreases, the trans-conductance gain of the transistors 33a and 33b increases, and the amplification factor increases. Accordingly, by changing the product VREX, the amplification factor of the differential amplifier 33 can be adjusted to an appropriate magnitude in accordance with the amplitude of the differential signal.

In the laser driver 22 of this embodiment, the variable capacitance element 33k may be constituted by the varactor diodes 33i and 33j. Accordingly, the configuration may suitably provide the variable capacitance element 33k for which the capacitance is easily controlled.

In the laser driver 22 of this embodiment, the variable resistor 33h may be constituted by an FET. Accordingly, the configuration may suitably provide the variable resistor 33h for which the resistance is easily controlled.

In the laser driver 22 of this embodiment, the output terminal of the driver 35 may be connected to the cathode of the laser diode 23, and the bias current source 39 that is connected in parallel to the driver 35 may be included. Accordingly, it is possible to reduce the driving current (output current) that flows through the driver 35. This configuration enables the driver 35 to operate faster.

Now, stabilization of the common potential of the driving signal Vmod is explained. In order to cause the driving transistor 35a to perform linear amplification all the time, an appropriate DC bias voltage needs to be applied to the control terminal (base) of the driving transistor 35a. For this purpose, it is preferable that the common potential of the driving signal Vmod be always maintained at a an appropriate value, which is independent of a voltage change in the power line 30a. Accordingly, the target potential circuit 37 and the adjusting circuit 38 are provided in the laser driver 22 of this embodiment. The adjusting circuit 38 controls the resistance of the variable resistor (transistor 38a) so that the common potential Vcom of the driving signal Vmod becomes substantially equal to the target potential Vtgt.

In the target potential circuit 37 of this embodiment, the variable current source 37a, the diode-connected transistor 37b that replicates the transistor 34a, the diode-connected transistor 37c that replicates the driving transistor 35a, and the resistor 37d that replicates the resistor 35b are connected in series in this order between the power line 30a and the reference potential line 30d. The target potential Vtgt is generated while including at least the sum of the voltage drops at the diode-connected transistors 37b and 37c and at the resistor 37d. Such a configuration of the target potential circuit 37 prevents the optical signal Ls from being distorted by easily providing the target potential Vtgt so that the minimum value of the control voltage of the driver 35 is maintained greater than the base-emitter voltage Vbe of the transistor 35a.

The current supplied by the variable current source 37a of the target potential circuit 37 is set to a value equal to one m-th (m is a real number and is preferably larger than 1) of the DC bias component Iout (DC) of the driving current (output current) Iout, for example. In this case, the resistance of the resistor 37d is m times that of the resistor 35b. Accordingly, it is possible to make the potential Ve2 between the diode-connected transistor 37c and the resistor 37d approach (preferably, substantially equal to) the potential Ve1 between the driving transistor 35a and the resistor 35b.

The voltage drops at the diode-connected transistors 37b and 37c are substantially equal to the corresponding voltage drops at the transistors 34a and 35a respectively but are slightly different from the corresponding voltage drops, to be exact. In the case where the voltage drops are slightly different, the target potential Vtgt can be obtained with high accuracy by fine adjustment of the current supplied by the variable current source 37a. If it is assumed that the base-emitter voltages Vbe of the transistors 34a, 35a, 37b, and 37c approximately coincide with one another, the target potential Vtgt is given by the following formula:

$$\begin{matrix}Vtgt ≅ 2 \times Vbe + Iout ( DC ) / RE \\ ≅ 2 \times Vbe + ( Iout ( DC ) / m ) \times ( m \times RE ) .\end{matrix}$$

In the adjusting circuit 38 of this embodiment, when the common potential Vcom of the driving signal Vmod is input to the non-inverting input terminal of the operational amplifier 38b, and the target potential Vtgt described above is input to the inverting input terminal of the operational amplifier 38b, the operational amplifier 38b amplifies the voltage difference between the input terminals and outputs the amplified voltage difference. The amplified voltage difference is input to the control terminal (gate) of the transistor 38a. The transistor 38a, which is a pMOS FET, operates in a triode region as a variable resistor. That is, when the potential (gate voltage) at the control terminal decreases relative to the potential at the other current terminal (source), the resistance between the current terminals (between the drain and the source) decreases and the common potential Vcom of the driving signal Vmod rises. In contrast, when the potential (gate voltage) at the control terminal increases relative to the potential at the other current terminal (source), the resistance between the current terminals (between the drain and the source) increases and the common potential Vcom of the driving signal Vmod decreases. Accordingly, when the adjusting circuit 38 detects the common potential Vcom of the driving signal Vmod and performs negative feedback control so that the detected value approaches the target potential Vtgt in the laser driver 22 of this embodiment. This configuration enables the laser driver 22 to always maintain the common potential Vcom at an appropriate value. As a result, the driver 35 may generate a suitable driving current (output current) without the multi-value signal being distorted.

Note that the laser driver according to this embodiment is not restricted to that in the aforementioned embodiment, and other various modifications are possible. In the aforementioned embodiment, a signal processing integrated circuit (IC) that generates a multi-value signal from an NRZ signal may be provided instead of the CDR circuit 15, for example. In the aforementioned embodiment, bipolar transistors are used as the transistors 32a1, 32b1, 33a, 33b, 34a, 35a, 37b, and 37c, for example; however, these transistors may be suitably replaced by FETs as needed. In this case, the gate corresponds to the control terminal, the drain corresponds to one of the current terminals, and the source corresponds to the other current terminal.

1. A laser driver for generating a driving current for a semiconductor laser element in response to a differential signal, the laser driver comprising:
a differential amplifier including
a first series circuit that includes a first transistor, a first resistor, and a first current source, the first transistor including a first current terminal, a second current terminal, and a control terminal, the first resistor including a first terminal and a second terminal, the first current source including a first terminal and a second terminal, the first terminal of the first resistor being connected to the first current terminal of the first transistor, the first terminal of the first current source being connected to the second current terminal of the first transistor,
a second series circuit that includes a second transistor, a second resistor, and a second current source, the second transistor including a first current terminal, a second current terminal, and a control terminal, the second resistor including a first terminal and a second terminal, the second current source including a first terminal and a second terminal, the first terminal of the second resistor being connected to the first current terminal of the second transistor, the first terminal of the second current source being connected to the second current terminal of the second transistor, the second terminal of the second resistor being connected to the second terminal of the first resistor, the second terminal of the second current source being connected to the second terminal of the first current source,
a variable resistor including a first terminal and a second terminal, the variable resistor having a variable resistance between the first terminal and the second terminal thereof, the first terminal of the variable resistor being connected to the second current terminal of the first transistor, the second terminal of the variable resistor being connected to the second current terminal of the second transistor, and
a variable capacitance element including a first terminal and a second terminal, the variable capacitance element having a variable capacitance between the first terminal and the second terminal thereof, the first terminal of the variable capacitance element being connected to the first terminal of the variable resistor, the second terminal of the variable capacitance element being connected to the second terminal of the variable resistor,
wherein the control terminal of the first transistor and the control terminal of the second transistor are configured to complimentarily receive the differential signal, and one of the first current terminal of the first transistor and the first current terminal of the second transistor is configured to output a driving signal in response to the differential signal; and
a driver configured to generate the driving current in response to the driving signal, and supply the driving current to the semiconductor laser element.

2. The laser driver according to claim 1, wherein
the variable resistor includes a first field-effect transistor including a control terminal and two current terminals, one of the two current terminal being connected to the second current terminal of the first transistor, another of the two current terminal being connected to the second current terminal of the second transistor, the first field-effect transistor having a resistance between the two current terminals thereof, the resistance being set in accordance with a first voltage provided to the control terminal of the first field-effect transistor, and
the variable capacitance element includes a pair of second field-effect transistors each including a control terminal and two current terminals, the two current terminals being connected to each other, each of the second field-effect transistors having a capacitance between the control terminal and the two current terminals thereof, the control terminal of one of the pair of the second field-effect transistors being connected to the one of the two current terminal of the variable resistor, the control terminal of another of the pair of the second field-effect transistors being connected to the another of the two current terminal of the variable transistor, the two current terminals of the one of the pair of the second field-effect transistors and the two current terminals of the another of the pair of the second filed-effect transistors are connected to each other and receiving a second voltage, the capacitances of the second field-effect transistors being set in accordance with the second voltage.

3. The laser driver according to claim 1, wherein
the driving signal has an amplitude proportional to an amplitude of the differential signal.

4. The laser driver according to claim 1, wherein
the driver includes a driving transistor including a first current terminal, a second current terminal, and a control terminal, the control terminal of the driving transistor receiving the driving signal, the first current terminal of the driving transistor outputting the driving current to the semiconductor laser element in response to the driving signal.

5. The laser driver according to claim 4, further comprising:
an adjusting circuit configured to adjust a potential at the second current terminal of the first resistor and the second current terminal of the second resistor so that the driving signal input to the control terminal of the driving transistor has a bottom level higher than a base-emitter voltage of the driving transistor.

6. The laser driver according to claim 1,
wherein the first transistor has a trans-conductance that increases when a current flowing through the first transistor increases, and decreases when the current flowing through the first transistor decreases, and
wherein the second transistor has another trans-conductance that increases when a current flowing through the second transistor increases, and decreases when the current flowing through the second transistor decreases.

7. The laser driver according to claim 1, further comprising:
a bias current source that is connected in parallel to the driver, is connected to the cathode of the semiconductor laser element, and supplies a direct current to the semiconductor laser element.

8. The laser driver according to claim 1, wherein
the differential amplifier complementarily changes a first current output from the first current terminal of the first transistor and a second current output from the first current terminal of the second transistor in response to the differential signal, and outputs, as the driving signal, one of a potential produced at the first current terminal of the first resistor in accordance with the first current and a potential produced at the first current terminal of the second resistor in accordance with the second current.

9. An optical transmitter for outputting an optical signal in response to a differential signal input from outside the optical transmitter, the optical transmitter comprising:
a laser driver including
a differential amplifier including
a first series circuit that includes a first transistor, a first resistor, and a first current source, the first transistor including a first current terminal, a second current terminal, and a control terminal, the first resistor including a first terminal and a second terminal, the first current source including a first terminal and a second terminal, the first terminal of the first resistor being connected to the first current terminal of the first transistor, the first terminal of the first current source being connected to the second current terminal of the first transistor,
a second series circuit that includes a second transistor, a second resistor, and a second current source, the second transistor including a first current terminal, a second current terminal, and a control terminal, the second resistor including a first terminal and a second terminal, the second current source including a first terminal and a second terminal, the first terminal of the second resistor being connected to the first current terminal of the second transistor, the first terminal of the second current source being connected to the second current terminal of the second transistor, the second terminal of the second resistor being connected to the second terminal of the first resistor, the second terminal of the second current source being connected to the second terminal of the first current source, and
a variable resistor including a first terminal and a second terminal, the variable resistor having a variable resistance between the first terminal and the second terminal thereof, the first terminal of the variable resistor being connected to the second current terminal of the first transistor, the second terminal of the variable resistor being connected to the second current terminal of the second transistor, and
a variable capacitance element including a first terminal and a second terminal, the variable capacitance element having a variable capacitance between the first terminal and the second terminal thereof, the first terminal of the variable capacitance element being connected to the first terminal of the variable resistor, the second terminal of the variable capacitance element being connected to the second terminal of the variable resistor,
wherein the control terminal of the first transistor and the control terminal of the second transistor are configured to complimentarily receive the differential signal, and one of the first current terminal of the first transistor and the first current terminal of the second transistor is configured to output a driving signal in response to the differential signal; and
a driver that includes an output terminal, generates a driving current in response to the driving signal, and outputs the driving current from the output terminal; and
a semiconductor laser element that includes a cathode and an anode and generates the optical signal in response to a current signal flowing from the anode to the cathode,
wherein the output terminal of the driver is connected to the cathode of the semiconductor laser element, and the semiconductor laser element changes a magnitude of the optical signal in accordance with an amplitude of the driving current.
